(19) United States
(12) Patent Application Publication
(10) Pub. No.: US 2024/0298441 A1
(43) Pub. Date: Sep. 5, 2024

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Hyo-Jung Kim, Suwon-si (KR); Donghoon Kwon, Suwon-si (KR)

(21) Appl. No.: 18/476,415

(22) Filed: Sep. 28, 2023

(30) Foreign Application Priority Data
Mar. 2, 2023 (KR) 10-2023-0027779

(51) Int. Cl. H10B 41/41; H01L 23/522; H01L 23/528; H01L 25/065; H10B 41/10; H10B 41/27; H10B 41/35; H10B 43/10; H10B 43/27; H10B 43/35; H10B 43/40; H10B 80/00

(52) U.S. Cl. CPC H10B 41/41; H01L 23/5226; H01L 23/5283; H01L 25/0652; H10B 41/10; H10B 41/27; H10B 41/35; H10B 43/10; H10B 43/27; H10B 43/35; H10B 43/40; H10B 80/00; H01L 2225/06506

(57) ABSTRACT

A semiconductor device may include a peripheral circuit structure, a source structure on the peripheral circuit structure, a first capacitor electrode on the peripheral circuit structure, an electrode insulating layer that at least partially surrounds the first capacitor electrode, a gate stack on the source structure, a memory channel structure that extends through the gate stack, a staircase insulating layer on the gate stack and the electrode insulating layer, a second capacitor electrode on the first capacitor electrode and that extends through the staircase insulating layer, and a penetration via that extends through the staircase insulating layer and the electrode insulating layer.

### CROSS-REFERENCE TO RELATED APPLICATIONS

This U.S. non-provisional patent application claims priority under 35 U.S.C. § 119 to Korean Patent Application No. 10-2023-0027779, filed on Mar. 2, 2023, in the Korean Intellectual Property Office, the entire contents of which are hereby incorporated by reference.

### TECHNICAL FIELD

The present disclosure relates to a semiconductor device and an electronic system including the same, and in particular, to a semiconductor device including capacitor electrodes and an electronic system including the same.

### BACKGROUND

Due to their small-sized, multifunctional, and/or low-cost characteristics, semiconductor devices are ubiquitous in the electronics industry. Semiconductor devices may be classified into a semiconductor memory device for storing data, a semiconductor logic device for processing data, and a hybrid semiconductor device including both memory and logic elements.

With the recent trend of high speed and low power consumption of electronic devices, semiconductor devices in the electronic devices may have high operating speeds and/or low operating voltages, and to satisfy these characteristics, it may be desirable to increase an integration density of the semiconductor device. However, as the integration density of the semiconductor device increases, the electrical characteristics and production yield of the semiconductor device may be diminished.

### SUMMARY

An embodiment of the present disclosure provides a semiconductor device with improved electrical and reliability characteristics and an electronic system including the same.

According to an embodiment of the present disclosure, a semiconductor device may include a peripheral circuit structure, a source structure on the peripheral circuit structure, a first capacitor electrode on the peripheral circuit structure, an electrode insulating layer that at least partially surrounds the first capacitor electrode, a gate stack on the source structure, a memory channel structure that extends through the gate stack, a staircase insulating layer on the gate stack and the electrode insulating layer, a second capacitor electrode on the first capacitor electrode and that extends through the staircase insulating layer, and a penetration via that extends through the staircase insulating layer and the electrode insulating layer.

According to an embodiment of the present disclosure, a semiconductor device may include a first source layer, a second source layer on the first source layer, a third source layer on the second source layer, a first capacitor electrode having a surface that is coplanar with a surface of the first source layer, an electrode insulating layer that at least partially surrounds the first capacitor electrode, a second capacitor electrode on the first capacitor electrode, a gate stack on the third source layer, a memory channel structure that extends through the gate stack, the memory channel structure including a channel layer and a memory layer that at least partially surrounds the channel layer, and a penetration via that extends through the electrode insulating layer. The second source layer extends through the memory layer and contacts the channel layer.

According to an embodiment of the present disclosure, an electronic system may include a main substrate, a semiconductor device on the main substrate, and a controller on the main substrate and connected to the semiconductor device. The semiconductor device may include a peripheral circuit structure, a source structure on the peripheral circuit structure, a first capacitor electrode on the peripheral circuit structure, an electrode insulating layer that at least partially surrounds the first capacitor electrode, a gate stack on the source structure, a memory channel structure that extends through the gate stack, a staircase insulating layer on the gate stack and the electrode insulating layer, a second capacitor electrode on the first capacitor electrode and that extends through the staircase insulating layer, and a penetration via that extends through the staircase insulating layer and the electrode insulating layer. The peripheral circuit structure may include a substrate, a transistor on the substrate, a peripheral circuit insulating layer on the transistor, a first peripheral conductive line within the peripheral circuit insulating layer, a second peripheral conductive line within the peripheral circuit insulating layer, and a connection via within the peripheral circuit insulating layer. The transistor, the first peripheral conductive line, and the connection via may be connected to the first capacitor electrode, and the second peripheral conductive line may be connected to the penetration via.

### BRIEF DESCRIPTION OF THE DRAWINGS

FIG. 1A is a schematic diagram illustrating an electronic system including a semiconductor device according to an embodiment of the present disclosure.

FIG. 1B is a perspective view schematically illustrating an electronic system including a semiconductor device according to an embodiment of the present disclosure.

FIGS. 1C and 1D are sectional views, each of which schematically illustrates a semiconductor package according to an embodiment of the present disclosure.

FIG. 2A is a plan view illustrating a semiconductor device according to an embodiment of the present disclosure.

FIG. 2B is a sectional view taken along a line A1-A1′ of FIG. 2A.

FIG. 2C is a sectional view taken along a line A2-A2′ of FIG. 2A.

FIG. 2D is a plan view illustrating a portion B of FIG. 2A taken at a level C of FIG. 2B.

FIG. 2E is a plan view illustrating the portion B of FIG. 2A taken at a level D of FIG. 2B.

FIG. 2F is a plan view illustrating the portion B of FIG. 2A taken at a level E of FIG. 2B.

FIG. 2G is a plan view illustrating the portion B of FIG. 2A taken at a level F of FIG. 2B.

FIG. 2H is an enlarged view illustrating a portion G of FIG. 2B.

FIGS. 3A, 3B, 3C, and 3D are sectional views illustrating a method of fabricating a semiconductor device according to an embodiment of the present disclosure.

FIG. 4 is a plan view illustrating a semiconductor device according to an embodiment of the present disclosure.

FIG. 5 is a plan view illustrating a semiconductor device according to an embodiment of the present disclosure.

FIG. 6 is a plan view illustrating a semiconductor device according to an embodiment of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. The term “connected” may be used herein to refer to a physical and/or electrical connection and may refer to a direct or indirect physical and/or electrical connection. As used herein, “an element A encloses an element B” may refer to element A partially or completely surrounding element B.

Example embodiments of the present disclosure will now be described more fully with reference to the accompanying drawings, in which example embodiments are shown.

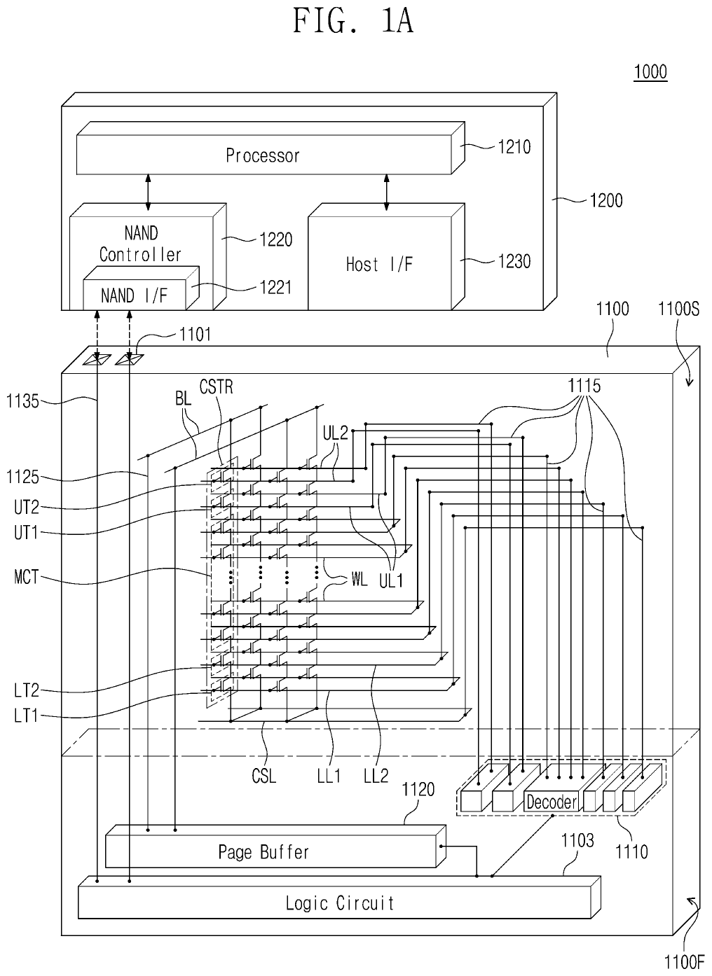

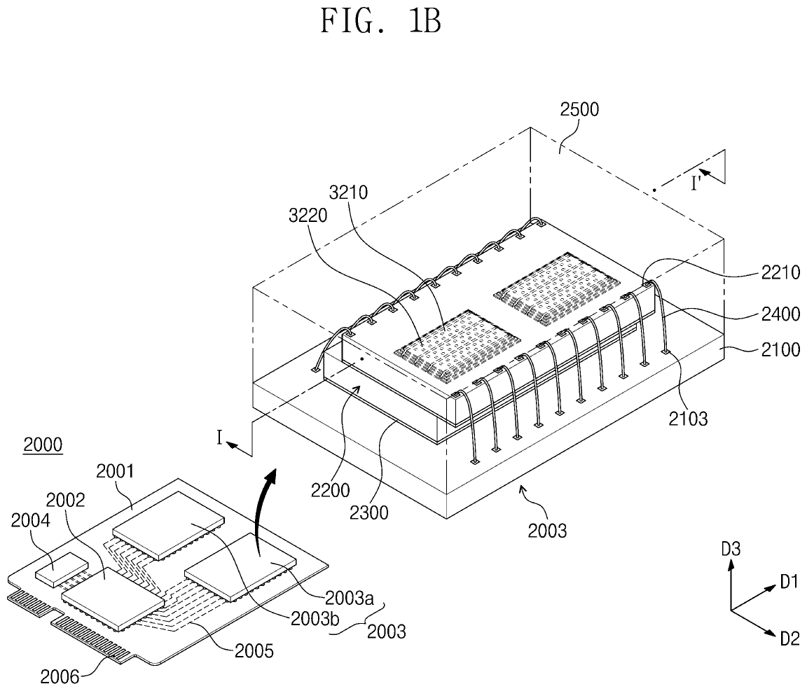

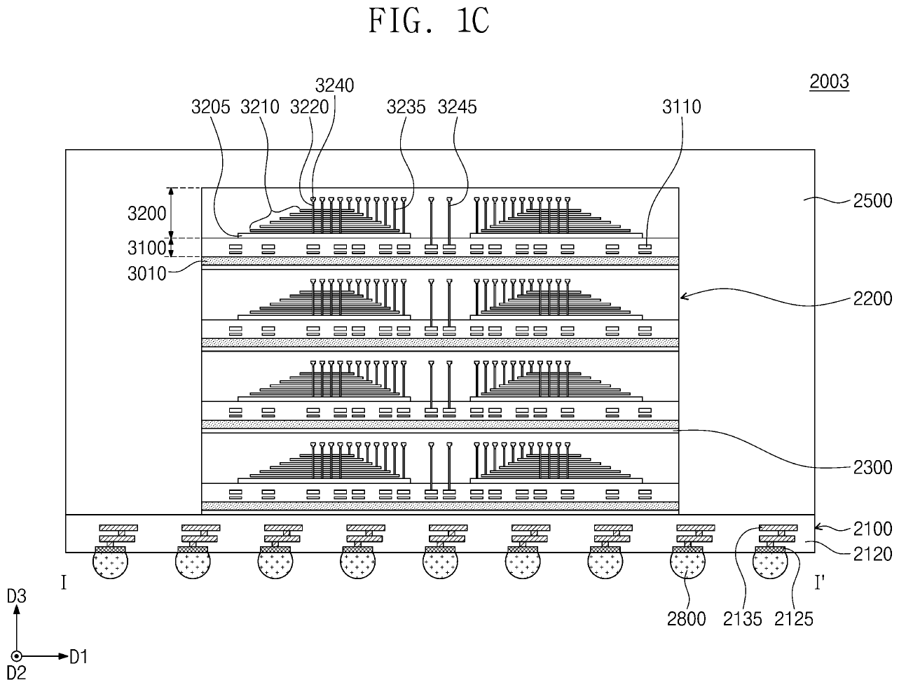

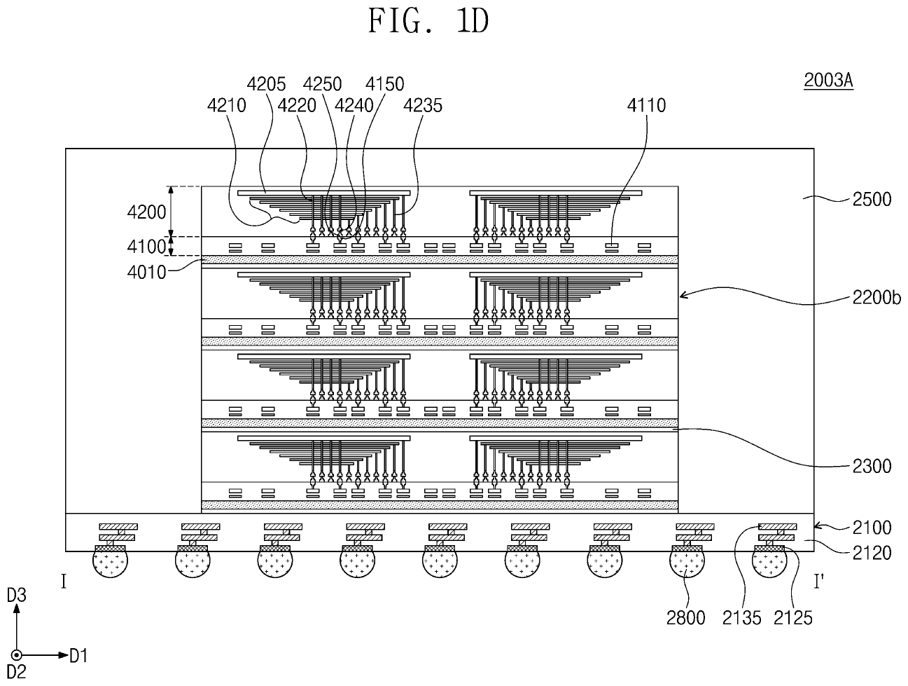

FIG. 1A is a schematic diagram illustrating an electronic system including a semiconductor device according to an embodiment of the present disclosure.

Referring to FIG. 1A, an electronic system 1000 according to an embodiment of the present disclosure may include a semiconductor device 1100 and a controller 1200, which is electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device and may be, for example, a NAND FLASH memory device. The semiconductor device 1100 may include a first structure 1100F and a second structure 1100S on the first structure 1100F. In an embodiment, the first structure 1100F may be adjacent to the second structure 1100S. The first structure 1100F may be a peripheral circuit structure, which includes a decoder circuit 1110, a page buffer 1120, and a logic circuit 1103. The second structure 1100S may be a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT, which are between the lower transistors LT1 and LT2 and the upper transistors UT1 and UT2. The number of the lower transistors LT1 and LT2 and the number of the upper transistors UT1 and UT2 may vary in other embodiments.

In an embodiment, the upper transistors UT1 and UT2 may include a string selection transistor, and the lower transistors LT1 and LT2 may include a ground selection transistor. The gate lower lines LL1 and LL2 may respectively operate as gate electrodes of the lower transistors LT1 and LT2. The word lines WL may operate as gate electrodes of the memory cell transistors MCT, and the gate upper lines UL1 and UL2 may operate as gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F to the second structure 1100S. The bit lines BL may be electrically connected to the page buffer 1120 through second connection lines 1125, which extend from the first structure 1100F to the second structure 1100S.

In the first structure 1100F, the decoder circuit 1110 and the page buffer 1120 may be configured to perform a control operation on at least selected one of the memory cell transistors MCT. The decoder circuit 1110 and the page buffer 1120 may be controlled by the logic circuit 1103. The semiconductor device 1100 may communicate with the controller 1200 through an input/output pad 1101, which is electrically connected to the logic circuit 1103. The input/output pad 1101 may be electrically connected to the logic circuit 1103 through an input/output connection line 1135, which extends from the first structure 1100F to the second structure 1100S.

The controller 1200 may include a processor 1210, a NAND controller 1220, and a host interface 1230. In an embodiment, the electronic system 1000 may include a plurality of semiconductor devices 1100, and in this case, the controller 1200 may be configured to control the semiconductor devices 1100.

The processor 1210 may control overall operations of the electronic system 1000 including the controller 1200. The processor 1210 may operate based on a specific firmware and may control the NAND controller 1220 to access the semiconductor device 1100. The NAND controller 1220 may include a NAND interface 1221 to communicate with the semiconductor device 1100. The NAND interface 1221 may transmit and receive control commands that control the semiconductor device 1100, data to be written into or read from the memory cell transistors MCT of the semiconductor device 1100, and so forth. The host interface 1230 may be configured to enable communication between the electronic system 1000 and an external host. When a control command is received from the external host through the host interface 1230, the processor 1210 may control the semiconductor device 1100 in response to the control command.

FIG. 1B is a perspective view schematically illustrating an electronic system including a semiconductor device according to an embodiment of the present disclosure.

Referring to FIG. 1B, an electronic system 2000 according to an embodiment of the present disclosure may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host. The number and arrangement of the pins of the connector 2006 may depend on a communication interface between the electronic system 2000 and the external host. In an embodiment, the electronic system 2000 may communicate with the external host in accordance with various known interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by electric power that is supplied from the external host through the connector 2006. The electronic system 2000 may further include a power management integrated circuit (PMIC) that is configured to distribute the electrical power to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which operates as a data storage device, and an external host. In an embodiment, the DRAM 2004 in the electronic system 2000 may serve as a cache memory and may be used as a storage space, which temporarily stores data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively in bottom surfaces of the semiconductor chips 2200, a connection structure 2400, which electrically connects the semiconductor chips 2200 to the package substrate 2100, and a molding layer 2500, which is provided on the package substrate 2100 to cover the semiconductor chips 2200 and the connection structure 2400.

The package substrate 2100 may be a printed circuit board, which includes package upper pads 2103. Each of the semiconductor chips 2200 may include an input/output pad 2210. The input/output pad 2210 may correspond to the input/output pad 1101 of FIG. 1A. Each of the semiconductor chips 2200 may include gate stacks 3210 and memory channel structures 3220. Each of the semiconductor chips 2200 may include a semiconductor device.

In an embodiment, the connection structure 2400 may be a bonding wire electrically connecting the input/output pad 2210 to the package upper pads 2103. Thus, in each of the first and second semiconductor packages 2003a and 2003b, the semiconductor chips 2200 may be electrically connected to each other in a bonding wire manner and may be electrically connected to the package upper pads 2103 of the package substrate 2100. Alternatively, in each of the first and second semiconductor packages 2003a and 2003b, the semiconductor chips 2200 may be electrically connected to each other by a connection structure including through-silicon vias (TSVs).

In an embodiment, the controller 2002 and the semiconductor chips 2200 may be included in a single package. In an embodiment, the controller 2002 and the semiconductor chips 2200 may be mounted on an additional interposer substrate different/separate from the main substrate 2001 and may be connected to each other through interconnection lines, which are provided in the interposer substrate.

FIGS. 1C and 1D are sectional views, each of which schematically illustrates a semiconductor package according to an embodiment of the present disclosure. Each of FIGS. 1C and 1D schematically illustrates an example of the semiconductor package 2003 of FIG. 1B taken along a line I-I′ of FIG. 1B.

Referring to FIG. 1C, in the semiconductor package 2003, the package substrate 2100 may be a printed circuit board. The package substrate 2100 may include a package substrate body portion 2120, package upper pads 2103 (shown in FIG. 1B) on a top surface of the package substrate body portion 2120, lower pads 2125 on or exposed through a bottom surface of the package substrate body portion 2120, and internal lines 2135 provided in the package substrate body portion 2120 to electrically connect the upper pads 2103 to the lower pads 2125. The upper pads 2103 may be electrically connected to the connection structures 2400 (shown in FIG. 1B). The lower pads 2125 may be connected to the interconnection patterns 2005 of the main substrate 2001 of the electronic system 2000, which is shown in FIG. 1B, through conductive connecting portions 2800.

Each of the semiconductor chips 2200 may include a semiconductor substrate 3010 and a first structure 3100 and a second structure 3200 that are sequentially stacked on the semiconductor substrate 3010. The first structure 3100 may include a peripheral circuit region provided with peripheral lines 3110. The second structure 3200 may include a common source line 3205, a gate stack 3210 on the common source line 3205, the memory channel structures 3220 that extend through the gate stack 3210, bit lines 3240 that are electrically connected to the memory channel structures 3220, and gate contact plugs 3235 that are electrically connected to the word lines WL of the gate stack 3210.

Each of the semiconductor chips 2200 may be electrically connected to the peripheral lines 3110 of the first structure 3100 and may include a penetration line 3245, which extends through the second structure 3200. The penetration line 3245 may be outside the gate stack 3210. In an embodiment, the penetration line 3245 may extend through the gate stack 3210. Each of the semiconductor chips 2200 may further include the input/output pad 2210 of FIG. 1B.

Referring to FIG. 1D, in a semiconductor package 2003A, each of semiconductor chips 2200a may include a semiconductor substrate 4010, a first structure 4100 on the semiconductor substrate 4010, and a second structure 4200, which is on and bonded to the first structure 4100 by a wafer bonding process. The first structure 4100 may include a peripheral circuit region, in which a peripheral line 4110 and first junction structures 4150 are provided. The second structure 4200 may include a common source line 4205, a gate stack 4210 between the common source line 4205 and the first structure 4100, memory channel structures 4220 that extend through the gate stack 4210, bit lines 4240 electrically connected to the memory channel structures 4220, gate contact plugs 4235 that are electrically connected to the word lines WL of FIG. 1A of the gate stack 4210, respectively, and second junction structures 4250. For example, the second junction structures 4250 may be electrically connected to the memory channel structures 4220, respectively, through the bit lines 4240, which are electrically connected to the memory channel structures 4220. The first junction structures 4150 of the first structure 4100 and the second junction structures 4250 of the second structure 4200 may be bonded to each other. In an embodiment, the bonding portion of the first and second junction structures 4150 and 4250 may be formed of copper (Cu). Each of the semiconductor chips 2200b may further include the input/output pad 2210 of FIG. 1B.

The semiconductor chips 2200 of FIG. 1C and the semiconductor chips 2200b of FIG. 1D may be electrically connected to each other by the connection structures 2400 of FIG. 1B, which are provided in the form of bonding wires. However, in an embodiment, semiconductor chips, which are provided in the same semiconductor package as the semiconductor chips 2200 of FIG. 1C or the semiconductor chips 2200b of FIG. 1D, may be electrically connected to each other through a connection structure including the through-silicon vias (TSVs).

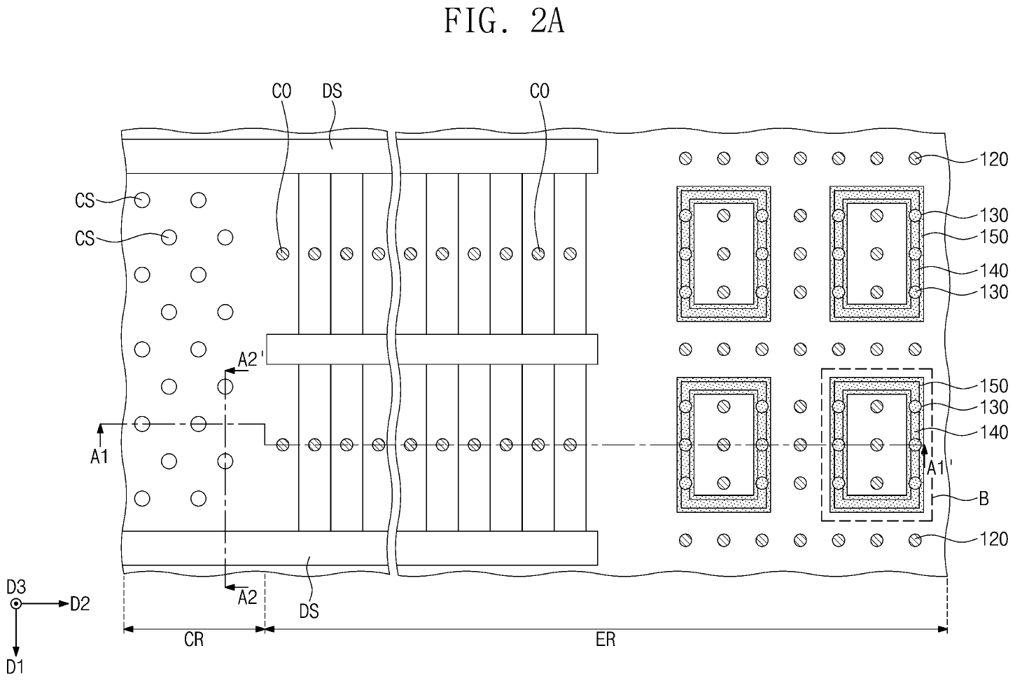

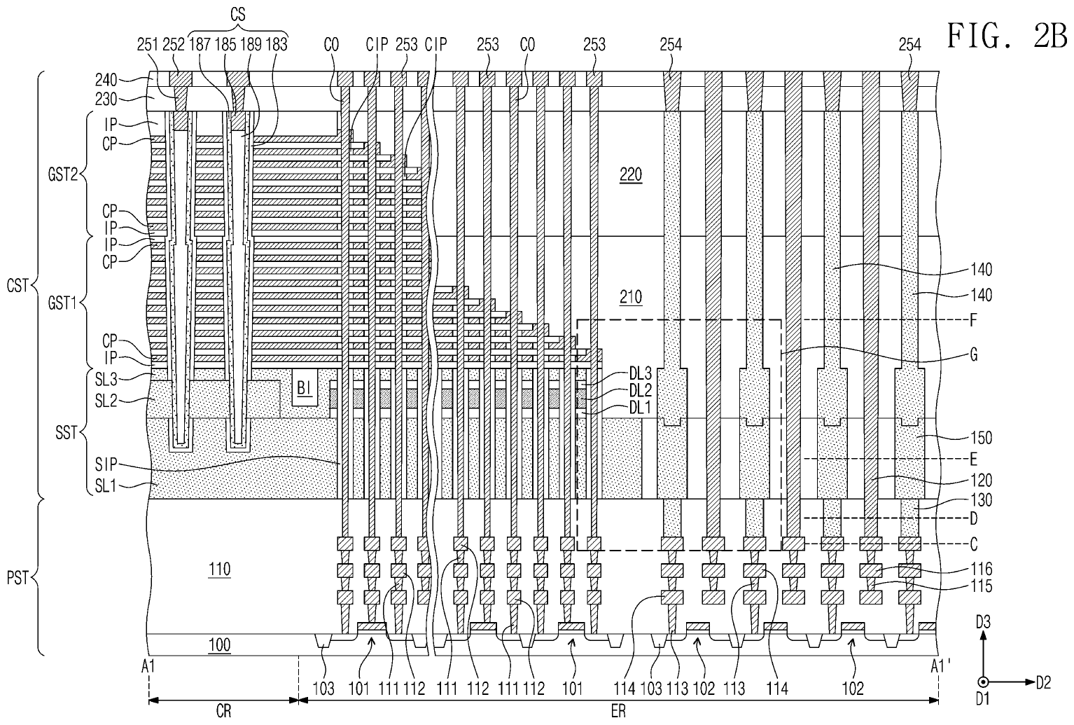

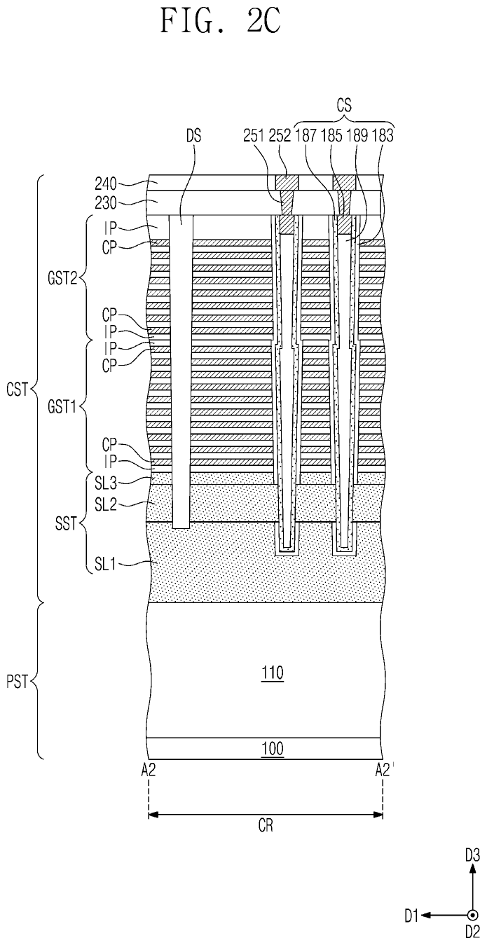

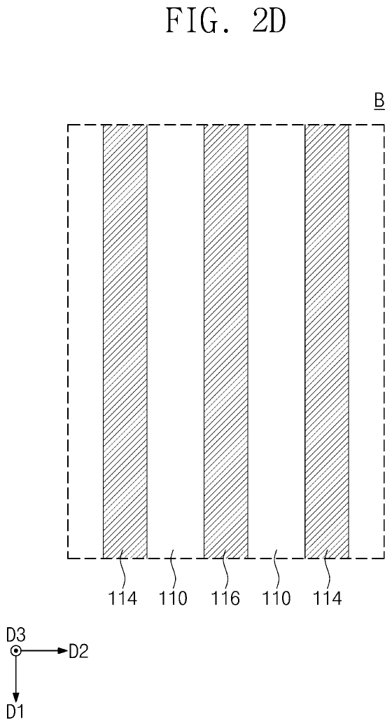

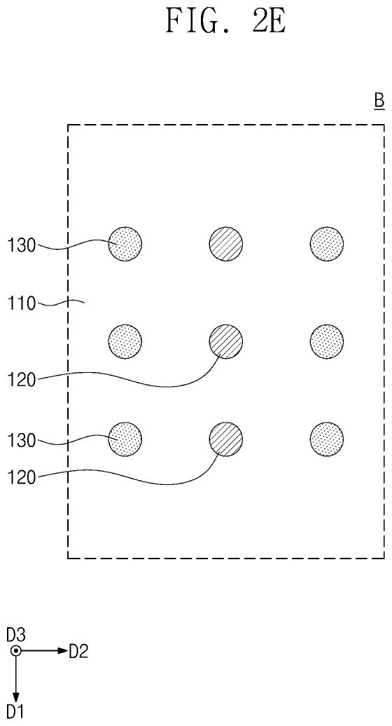

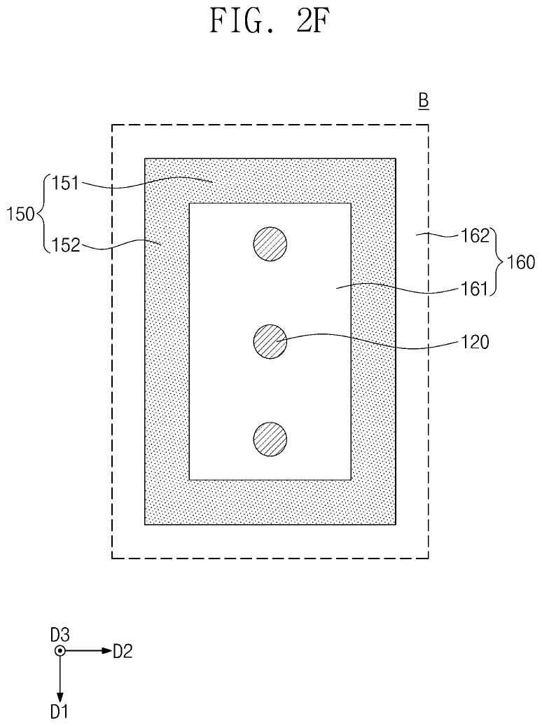

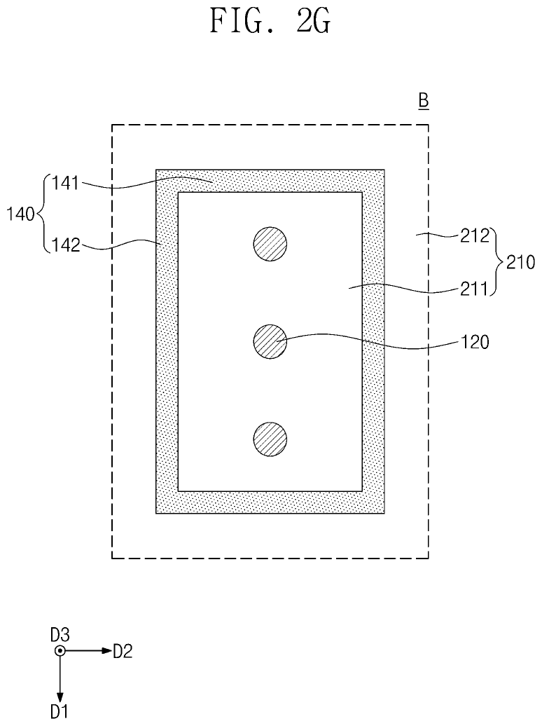

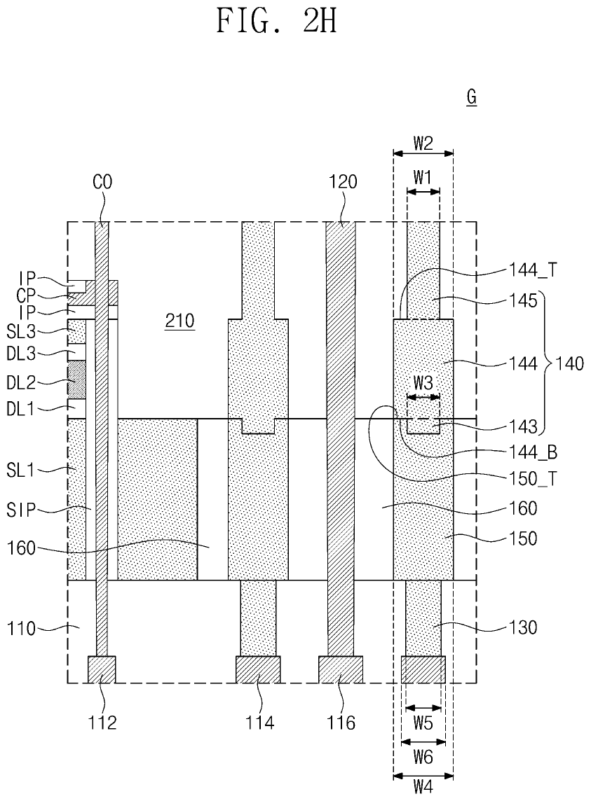

FIG. 2A is a plan view illustrating a semiconductor device according to an embodiment of the present disclosure. FIG. 2B is a sectional view taken along a line A1-A1′ of FIG. 2A. FIG. 2C is a sectional view taken along a line A2-A2′ of FIG. 2A. FIG. 2D is a plan view illustrating a portion B of FIG. 2A taken at a level C of FIG. 2B. FIG. 2E is a plan view illustrating the portion B of FIG. 2A taken at a level D of FIG. 2B. FIG. 2F is a plan view illustrating the portion B of FIG. 2A taken at a level E of FIG. 2B. FIG. 2G is a plan view illustrating the portion B of FIG. 2A taken at a level F of FIG. 2B. FIG. 2H is an enlarged view illustrating a portion G of FIG. 2B.

Referring to FIGS. 2A, 2B, and 2C, a semiconductor device may include a peripheral circuit structure PST and a memory cell structure CST on the peripheral circuit structure PST.

The peripheral circuit structure PST may include a substrate 100. The substrate 100 may be a plate-shaped structure that extends parallel to a plane defined by a first direction D1 and a second direction D2. The first and second directions D1 and D2 may not be parallel to each other. In an embodiment, the first and second directions D1 and D2 may be two different horizontal directions, which are orthogonal to each other. In an embodiment, the substrate 100 may be a semiconductor substrate. As an example, the substrate 100 may be formed of or include silicon, germanium, silicon-germanium, GaP, or GaAs. In an embodiment, the substrate 100 may be a silicon-on-insulator (SOI) substrate or a germanium-on-insulator (GOI) substrate.

The substrate 100 may include a cell region CR and an extension region ER. The cell region CR and the extension region ER may be two distinct regions of the substrate 100 when viewed in a plan view defined by the first and second directions D1 and D2.

The peripheral circuit structure PST may include a peripheral circuit insulating layer 110 provided on the substrate 100. The peripheral circuit insulating layer 110 may be formed of or include an insulating material. As an example, the peripheral circuit insulating layer 110 may be formed of or include at least one of oxide or nitride materials. In an embodiment, the peripheral circuit insulating layer 110 may comprise a plurality of insulating layers.

The peripheral circuit structure PST may further include first transistors 102 and second transistors 101. The first transistors 102 and the second transistors 101 may be provided between the substrate 100 and the peripheral circuit insulating layer 110. In an embodiment, each of the first and second transistors 102 and 101 may include source/drain regions, a gate electrode, and a gate insulating layer. Device isolation layers 103 may be provided in the substrate 100. The first and second transistors 102 and 101 may be between the device isolation layers 103. The device isolation layer 103 may be formed of or include an insulating material.

The peripheral circuit structure PST may include first peripheral contacts 113, second peripheral contacts 115, third peripheral contacts 111, first peripheral conductive lines 114, second peripheral conductive lines 116, and third peripheral conductive lines 112.

The first peripheral contact 113 and the first peripheral conductive line 114 may be electrically connected to the first transistor 102. The first peripheral contact 113 and the first peripheral conductive line 114 may be electrically connected to a connection via 130, a first capacitor electrode 150, a second capacitor electrode 140, and an electrode contact 254, which will be described below. The second peripheral contact 115 and the second peripheral conductive line 116 may be electrically connected to a penetration via 120, which will be described below. The second peripheral contact 115 and the second peripheral conductive line 116 may be electrically isolated from the first peripheral contact 113 and the first peripheral conductive line 114. The third peripheral contact 111 and the third peripheral conductive line 112 may be electrically connected to the second transistor 101. The third peripheral contact 111 and the third peripheral conductive line 112 may be electrically connected to a connection contact CO and a connection conductive line 253, which will be described below.

The first to third peripheral contacts 113, 115, and 111 and the first to third peripheral conductive lines 114, 116, and 112 may be provided in the peripheral circuit insulating layer 110. The first to third peripheral contacts 113, 115, and 111 and the first to third peripheral conductive lines 114, 116, and 112 may be formed of or include conductive materials. For example, the first to third peripheral contacts 113, 115, and 111 and the first to third peripheral conductive lines 114, 116, and 112 may be formed of or include metallic materials.

The peripheral circuit structure PST may further include connection vias 130. The connection via 130 may be provided on the first peripheral conductive line 114. A bottom surface of the connection via 130 may be in contact with a top surface of the first peripheral conductive line 114. The connection via 130 may be formed of or include conductive materials. As an example, the connection via 130 may be formed of or include poly silicon.

The memory cell structure CST may include a source structure SST, first capacitor electrodes 150, an electrode insulating layer 160, a first gate stack GST1, a second gate stack GST2, memory channel structures CS, division structures DS, a first staircase insulating layer 210, a second staircase insulating layer 220, second capacitor electrodes 140, a first cover insulating layer 230, a second cover insulating layer 240, bit line contacts 251, bit lines 252, connection contacts CO, connection conductive lines 253, electrode contacts 254, and penetration vias 120.

The source structure SST may include a first source layer SL1 provided on the peripheral circuit structure PST, a second source layer SL2 provided on the first source layer SL1, a first dummy layer DL1, a second dummy layer DL2, and a third dummy layer DL3 provided on the first source layer SL1, and a third source layer SL3 provided on the second source layer SL2 and the first to third dummy layers DL1, DL2, and DL3.

The first to third source layers SL1, SL2, and SL3 may be formed of or include conductive materials. As an example, the first to third source layers SL1, SL2, and SL3 may be formed of or include poly silicon. The second source layer SL2 may be within the cell region CR. The second source layer SL2 may operate as a common source line.

The first dummy layer DL1, the second dummy layer DL2, and the third dummy layer DL3 may be sequentially provided on the first source layer SL1 in a third direction D3. The third direction D3 may not be parallel to the first and second directions D1 and D2. As an example, the third direction D3 may be a vertical direction that is orthogonal to the first and second directions D1 and D2. The first to third dummy layers DL1, DL2, and DL3 may be within the extension region ER. The first to third dummy layers DL1, DL2, and DL3 may be at the same level as the second source layer SL2. The first to third dummy layers DL1, DL2, and DL3 may be formed of or include insulating materials. In an embodiment, the first and third dummy layers DL1 and DL3 may be formed of or include the same insulating material, and the second dummy layer DL2 may be formed of or include an insulating material different from the first and third dummy layers DL1 and DL3. As an example, the second dummy layer DL2 may be formed of or include nitride, and the first and third dummy layers DL1 and DL3 may be formed of or include oxide.

The third source layer SL3 may be on the second source layer SL2 and the first to third dummy layers DL1, DL2, and DL3. The third source layer SL3 may extend from the cell region CR to the extension region ER.

In an embodiment, the source structure SST may further include an insulating gapfill layer BI on the third source layer SL3. The insulating gapfill layer BI may be provided between the cell region CR and the extension region ER. The insulating gapfill layer BI may be provided between the second source layer SL2 and the first to third dummy layers DL1, DL2, and DL3. The second source layer SL2 may be spaced apart from the first to third dummy layers DL1, DL2, and DL3 in the second direction D2, and the insulating gapfill layer BI and a portion of the third source layer SL3 enclosing the insulating gapfill layer BI may be interposed between the second source layer SL2 and the first to third dummy layers DL1, DL2, and DL3. The insulating gapfill layer BI may be formed of or include an insulating material.

The source structure SST may further include source insulating patterns SIP, which extend through the first source layer SL1, the first to third dummy layers DL1, DL2, and DL3, and the third source layer SL3 in the third direction D3. The source insulating pattern SIP may enclose the connection contact CO. The source insulating pattern SIP may be formed of or include an insulating material.

The first capacitor electrode 150 may be provided on the connection via 130 and the peripheral circuit insulating layer 110 of the peripheral circuit structure PST. A bottom surface of the first capacitor electrode 150 may contact a top surface of the connection via 130. The first capacitor electrode 150 may be at the same level as the first source layer SL1 of the source structure SST. The first capacitor electrode 150 may be formed of or include a conductive material. In an embodiment, the first capacitor electrode 150 may be formed of or include the same conductive material as the first source layer SL1. As an example, the first capacitor electrode 150 may be formed of or include poly silicon.

The electrode insulating layer 160 may be provided on the peripheral circuit insulating layer 110 of the peripheral circuit structure PST. The electrode insulating layer 160 may be at the same level as the first source layer SL1 and the first capacitor electrode 150 of the source structure SST. The electrode insulating layer 160 may enclose the first capacitor electrode 150. The electrode insulating layer 160 may be formed of or include an insulating material. As an example, the electrode insulating layer 160 may be formed of or include oxide.

The first gate stack GST1 may be provided on the third source layer SL3 of the source structure SST. The second gate stack GST2 may be provided on the first gate stack GST1. The number of the gate stacks GST1 and GST2 may not be limited to the illustrated example. In an embodiment, the number of the gate stacks GST1 and GST2 may be one or may be greater than three.

Each of the first and second gate stacks GST1 and GST2 may include insulating patterns IP and conductive patterns CP, which are alternately stacked on top of one another in the third direction D3. The insulating patterns IP and the conductive patterns CP may be provided to define a staircase structure.

The insulating patterns IP may be formed of or include an insulating material. As an example, the insulating patterns IP may be formed of or include oxide. The conductive patterns CP may be formed of or include a conductive material. As an example, the conductive patterns CP may be formed of or include tungsten.

Each of the first and second gate stacks GST1 and GST2 may further include contact insulating patterns CIP. The contact insulating pattern CIP may be at the same level as the conductive pattern CP. The contact insulating pattern CIP may enclose the connection contact CO. The contact insulating pattern CIP may be between the connection contact CO and the conductive pattern CP. The contact insulating pattern CIP may be formed of or include an insulating material. As an example, the contact insulating pattern CIP may be formed of or include oxide.

The first staircase insulating layer 210 may be on the first gate stack GST1, the first source layer SL1, and the electrode insulating layer 160. The first staircase insulating layer 210 may be on or cover the staircase structure of the first gate stack GST1. The first staircase insulating layer 210 may contact a top surface of the first source layer SL1 and a top surface of the electrode insulating layer 160. The first staircase insulating layer 210 may be at the same level as the first gate stack GST1. A top surface of the first gate stack GST1 may be at the same level as a top surface of the first staircase insulating layer 210. In an embodiment, the first staircase insulating layer 210 may enclose the first gate stack GST1.

The second staircase insulating layer 220 may be provided on the first staircase insulating layer 210. The second staircase insulating layer 220 may cover the staircase structure of the second gate stack GST2. The second staircase insulating layer 220 may be at the same level as the second gate stack GST2. A top surface of the second gate stack GST2 may be at the same level as a top surface of the second staircase insulating layer 220. In an embodiment, the second staircase insulating layer 220 may enclose the second gate stack GST2. The first and second staircase insulating layers 210 and 220 may be formed of or include insulating materials. As an example, the first and second staircase insulating layers 210 and 220 may be formed of or include oxide.

The memory channel structures CS may extend in the third direction D3 to through the first gate stack GST1, the second gate stack GST2, the third source layer SL3, and the second source layer SL2. Each of the memory channel structures CS may include an insulating capping layer 189, a channel layer 187 enclosing the insulating capping layer 189, and a memory layer 183 enclosing the channel layer 187. The memory channel structures CS may be within the cell region CR.

The insulating capping layer 189 may be formed of or include an insulating material. As an example, the insulating capping layer 189 may be formed of or include an oxide material. The channel layer 187 may be formed of or include a conductive material. As an example, the channel layer 187 may be formed of or include poly silicon. The channel layer 187 may be electrically connected to the second source layer SL2. The second source layer SL2 may extend through the memory layer 183 and may contact the channel layer 187.

The memory layer 183 may be configured to store data. In an embodiment, the memory layer 183 may include a tunnel insulating layer enclosing the channel layer 187, a data storing layer enclosing the tunnel insulating layer, and a blocking layer enclosing the data storing layer.

Each of the memory channel structures CS may further include a bit line pad 185 provided on the channel layer 187. The bit line pad 185 may be formed of or include a conductive material. As an example, the bit line pad 185 may be formed of or include at least one of poly silicon or metallic materials.

The division structures DS may be provided to extend through the first and second gate stacks GST1 and GST2. The division structures DS may extend in the second direction D2. The division structure DS may be formed of or include an insulating material. In an embodiment, the division structure DS may further include a conductive material enclosed by the insulating material.

The second capacitor electrode 140 may be provided on the first capacitor electrode 150. The second capacitor electrode 140 may contact the first capacitor electrode 150. The second capacitor electrode 140 may extend through the first and second staircase insulating layers 210 and 220. A top surface of the second capacitor electrode 140 may be at the same level as a top surface of the division structure DS. The top surface of the second capacitor electrode 140, the top surface of the division structure DS, and the top surface of the second staircase insulating layer 220 may be coplanar with each other. The second capacitor electrode 140 may be formed of or include a conductive material. In an embodiment, the second capacitor electrode 140 may be formed of or include the same conductive material as the first capacitor electrode 150. As an example, the second capacitor electrode 140 may be formed of or include poly silicon.

The first cover insulating layer 230 may be provided on the second gate stack GST2, the second staircase insulating layer 220, the memory channel structure CS, the division structure DS, and the second capacitor electrode 140. The first cover insulating layer 230 may be formed of or include an insulating material. The second cover insulating layer 240 may be provided on the first cover insulating layer 230. The second cover insulating layer 240 may include an insulating material.

The bit line contact 251 may be provided within the first cover insulating layer 230. The bit line contact 251 may be provided on the bit line pad 185 of the memory channel structure CS. The bit line 252 may be provided within the second cover insulating layer 240. The bit line 252 may be provided on the bit line contact 251. The bit line 252, the bit line contact 251, the memory channel structure CS, and the second source layer SL2 may be electrically connected to each other. The bit line contact 251 and the bit line 252 may be formed of or include conductive materials.

The connection contact CO may be extended in the third direction D3. The connection contact CO may extend through the first cover insulating layer 230, at least one of the second staircase insulating layer 220 and the second gate stack GST2, at least one of the first staircase insulating layer 210 and the first gate stack GST1, the third source layer SL3, the third dummy layer DL3, the second dummy layer DL2, the first dummy layer DL1, the first source layer SL1, and the source insulating pattern SIP. The connection contact CO may be connected to the third peripheral conductive line 112.

The connection conductive line 253 may be provided within the second cover insulating layer 240. The connection conductive line 253 may be provided on the connection contact CO. The connection conductive line 253, the connection contact CO, the third peripheral conductive line 112, the third peripheral contact 111, and the second transistor 101 may be electrically connected to each other. The connection contact CO and the connection conductive line 253 may be formed of or include conductive materials.

The electrode contact 254 may extend through the first cover insulating layer 230 and the second cover insulating layer 240. The electrode contact 254 may be provided on the second capacitor electrode 140. The electrode contact 254, the second capacitor electrode 140, the first capacitor electrode 150, the connection via 130, the first peripheral conductive line 114, the first peripheral contact 113, and the first transistor 102 may be electrically connected to each other. The electrode contact 254 may be formed of or include a conductive material.

The penetration via 120 may extend through the second cover insulating layer 240, the first cover insulating layer 230, the second staircase insulating layer 220, the first staircase insulating layer 210, and the electrode insulating layer 160. The penetration via 120 may be on the second peripheral conductive line 116. A bottom surface of the penetration via 120 may contact a top surface of the second peripheral conductive line 116. The penetration via 120 may be formed of or include conductive materials. The penetration via 120, the second peripheral conductive line 116, and the second peripheral contact 115 may be electrically connected to each other. The penetration via 120, the second peripheral conductive line 116, and the second peripheral contact 115 may be electrically isolated from the electrode contact 254, the second capacitor electrode 140, the first capacitor electrode 150, the connection via 130, the first peripheral conductive line 114, the first peripheral contact 113 and the first transistor 102.

Referring to FIG. 2D, the first and second peripheral conductive lines 114 and 116 may extend parallel to each other. As an example, the first and second peripheral conductive lines 114 and 116 may extend in the first direction D1. The first and second peripheral conductive lines 114 and 116 may be alternately arranged in the second direction D2.

A portion of the peripheral circuit insulating layer 110 may be interposed between the first and second peripheral conductive lines 114 and 116.

Referring to FIG. 2E, the connection via 130 may be spaced apart from the penetration via 120. The connection vias 130 and the penetration vias 120 may be enclosed by the peripheral circuit insulating layer 110. A portion of the peripheral circuit insulating layer 110 may be interposed between the connection via 130 and the penetration via 120.

The arrangement of the connection vias 130 and penetration vias 120 is not limited to the illustrated example. In an embodiment, the penetration via 120 and the connection via 130 may be arranged to be offset from each other.

Referring to FIG. 2F, the first capacitor electrode 150 may enclose the penetration vias 120. In an embodiment, the number of the penetration vias 120, which are enclosed by the first capacitor electrode 150, may be less than two or may be greater than four.

The first capacitor electrode 150 may include two first extended portions 151, which extend in the second direction D2, and two second extended portions 152, which extend in the first direction D1. The second extended portions 152 may be respectively connected to opposite end portions of the first extended portion 151 of the first capacitor electrode 150. The penetration vias 120 may be enclosed by the first and second extended portions 151 and 152 of the first capacitor electrode 150.

The electrode insulating layer 160 may include a first electrode insulating portion 161 and a second electrode insulating portion 162. The first electrode insulating portion 161 may enclose the penetration vias 120. The first capacitor electrode 150 may enclose the first electrode insulating portion 161. The second electrode insulating portion 162 may enclose the first capacitor electrode 150.

Referring to FIG. 2G, the second capacitor electrode 140 may enclose the penetration vias 120. In an embodiment, the number of the penetration vias 120, which are enclosed by the second capacitor electrode 140, may be less than two or may be greater than four.

The second capacitor electrode 140 may include two first extended portions 141, which extend in the second direction D2, and two second extended portions 142, which extend in the first direction D1. The second extended portions 142 may be respectively connected to opposite end portions of the first extended portion 141 of the second capacitor electrode 140. The penetration vias 120 may be enclosed by the first and second extended portions 141 and 142 of the second capacitor electrode 140.

The first staircase insulating layer 210 may include a first staircase insulating portion 211 and a second staircase insulating portion 212. The first staircase insulating portion 211 may enclose the penetration vias 120. The second capacitor electrode 140 may enclose the first staircase insulating portion 211. The second staircase insulating portion 212 may enclose the second capacitor electrode 140.

Referring to FIG. 2H, the second capacitor electrode 140 may include a first portion 143 in the first capacitor electrode 150, a second portion 144 on the first portion 143, and a third portion 145 on the second portion 144. The second portion 144 of the second capacitor electrode 140 may be at a level that is higher than the first portion 143 of the second capacitor electrode 140. The third portion 145 of the second capacitor electrode 140 may be at a level that is higher than the second portion 144 of the second capacitor electrode 140.

A width of the third portion 145 of the second capacitor electrode 140 may be less than a width of the second portion 144 of the second capacitor electrode 140. As an example, a width W1 of the third portion 145 of the second capacitor electrode 140 in the second direction D2 may be less than a width W2 of the second portion 144 of the second capacitor electrode 140 in the second direction D2.

The width of the third portion 145 of the second capacitor electrode 140 may be greater than the width of the first portion 143 of the second capacitor electrode 140. As an example, the width W1 of the third portion 145 of the second capacitor electrode 140 in the second direction D2 may be greater than a width W3 of the first portion 143 of the second capacitor electrode 140 in the second direction D2.

The first portion 143 of the second capacitor electrode 140 may be enclosed by an upper portion of the first capacitor electrode 150. A bottom surface 144_B of the second portion 144 of the second capacitor electrode 140 may be in contact with a top surface 150_T of the first capacitor electrode 150.

A width of the first capacitor electrode 150 may be larger than widths of the first and third portions 143 and 145 of the second capacitor electrode 140. As an example, a width W4 of the first capacitor electrode 150 in the second direction D2 may be larger than the widths W1 and W3 of the first and third portions 143 and 145 of the second capacitor electrode 140 in the second direction D2.

In an embodiment, the width of the first capacitor electrode 150 may be equal to the width of the second portion 144 of the second capacitor electrode 140. As an example, the width W4 of the first capacitor electrode 150 in the second direction D2 may be equal to the width W2 of the second portion 144 of the second capacitor electrode 140 in the second direction D2.

A width of the connection via 130 may be less than the width of the first capacitor electrode 150 and the width of the first peripheral conductive line 114. As an example, a width W5 of the connection via 130 in the second direction D2 may be less than the width W4 of the first capacitor electrode 150 in the second direction D2 and a width W6 of the first peripheral conductive line 114 in the second direction D2.

A bottom surface of the connection via 130 may be at the same level as a bottom surface of the penetration via 120. A top surface of the connection via 130 may be at the same level as a top surface of the peripheral circuit insulating layer 110.

A bottom surface of the first capacitor electrode 150, a bottom surface of the electrode insulating layer 160, a bottom surface of the source insulating pattern SIP, and a bottom surface of the first source layer SL1 may be at the same level. The bottom surface of the first capacitor electrode 150, the bottom surface of the electrode insulating layer 160, the bottom surface of the source insulating pattern SIP, and the bottom surface of the first source layer SL1 may be coplanar with each other. The top surface 150_T of the first capacitor electrode 150, the top surface of the electrode insulating layer 160, the top surface of the source insulating pattern SIP, and the top surface of the first source layer SL1 may be at the same level. The top surface 150_T of the first capacitor electrode 150, the top surface of the electrode insulating layer 160, the top surface of the source insulating pattern SIP, and the top surface of the first source layer SL1 may be coplanar with each other.

The bottom surface 144_B of the second portion 144 of the second capacitor electrode 140 may be at the same level as a bottom surface of the first staircase insulating layer 210 and a bottom surface of the first dummy layer DL1. A top surface 144_T of the second portion 144 of the second capacitor electrode 140 may be at the same level as a top surface of the third source layer SL3 and the top surface of the source insulating pattern SIP. The top surface 144_T of the second portion 144 of the second capacitor electrode 140 may contact the first staircase insulating layer 210.

A width of the penetration via 120 may decrease as a vertical level is lowered. The penetration via 120 may have an even or flat sidewall. The penetration via 120 may include portions that are at the same levels as the connection via 130, the first capacitor electrode 150, and the second capacitor electrode 140, respectively.

A semiconductor device according to an embodiment of the present disclosure may include a capacitor structure including first and second capacitor electrode structures, where the first capacitor electrode structure includes the electrode contact 254, the second capacitor electrode 140, the first capacitor electrode 150, the connection via 130, the first peripheral conductive line 114, and the first peripheral contact 113, and the second capacitor electrode structure includes the penetration via 120, the second peripheral conductive line 116, and the second peripheral contact 115. Since the first capacitor electrode structure includes the electrode contact 254, the second capacitor electrode 140, the first capacitor electrode 150, the connection via 130, the first peripheral conductive line 114, and the first peripheral contact 113, the first capacitor electrode structure may have a relatively large size. Furthermore, since the second capacitor electrode structure includes the penetration via 120, the second peripheral conductive line 116, and the second peripheral contact 115, the second capacitor electrode structure may have a relatively large size. Accordingly, a capacitor structure with relatively large capacitance may be provided by the semiconductor devices of the present disclosure.

According to an embodiment of the present disclosure, since the first and second capacitor electrodes 150 and 140 of the semiconductor device include the first and second extended portions 151, 152, 141, and 152, the semiconductor devices of the present disclosure prevent or reduce a leaning issue of the first and second capacitor electrodes 150 and 140 in a process of forming the first and second capacitor electrodes 150 and 140.

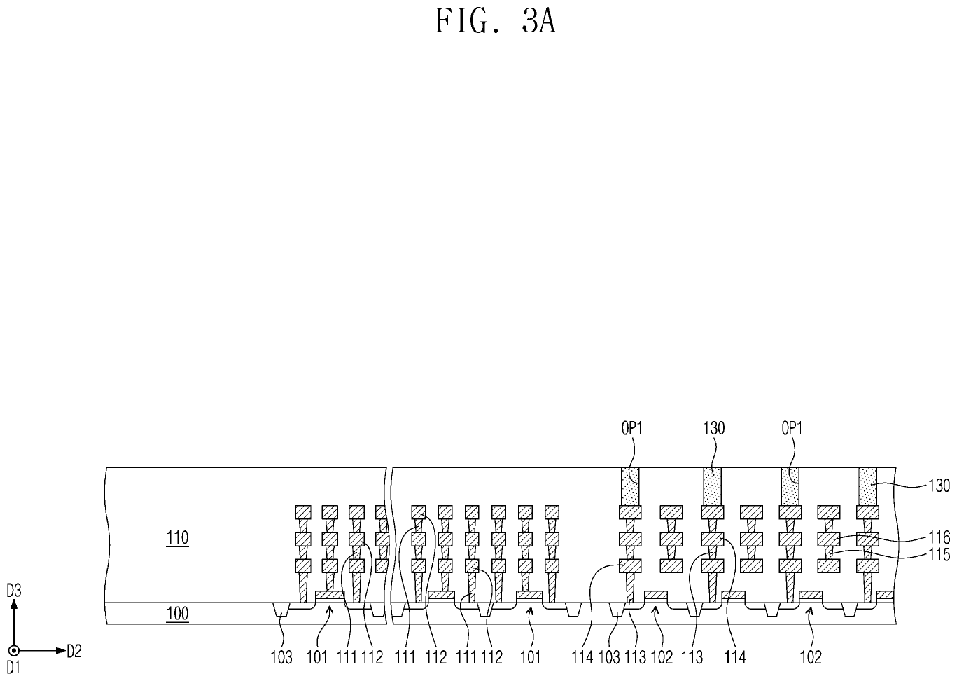

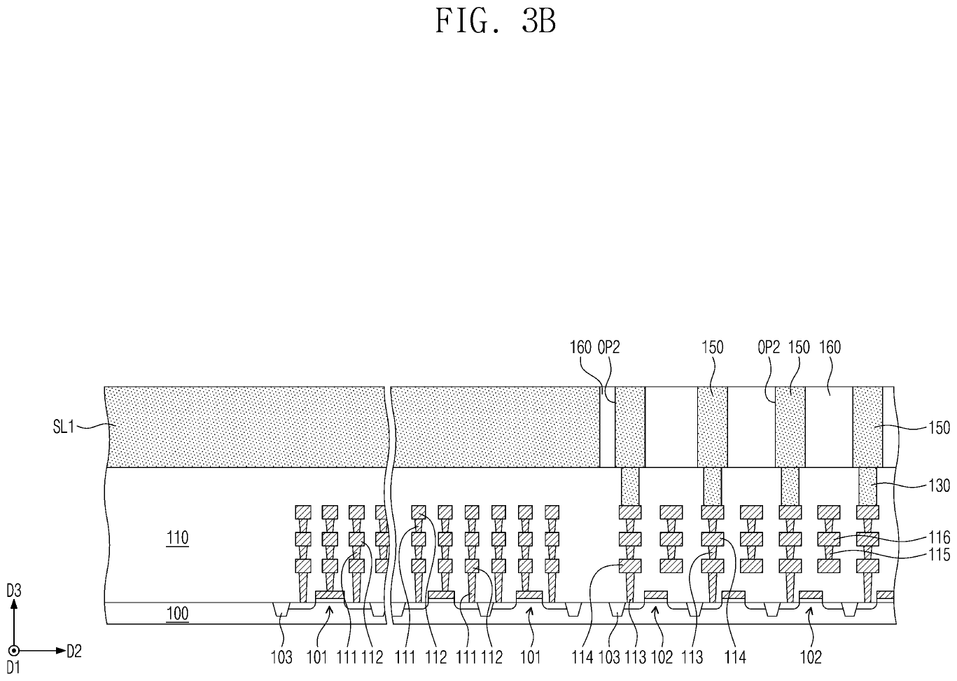

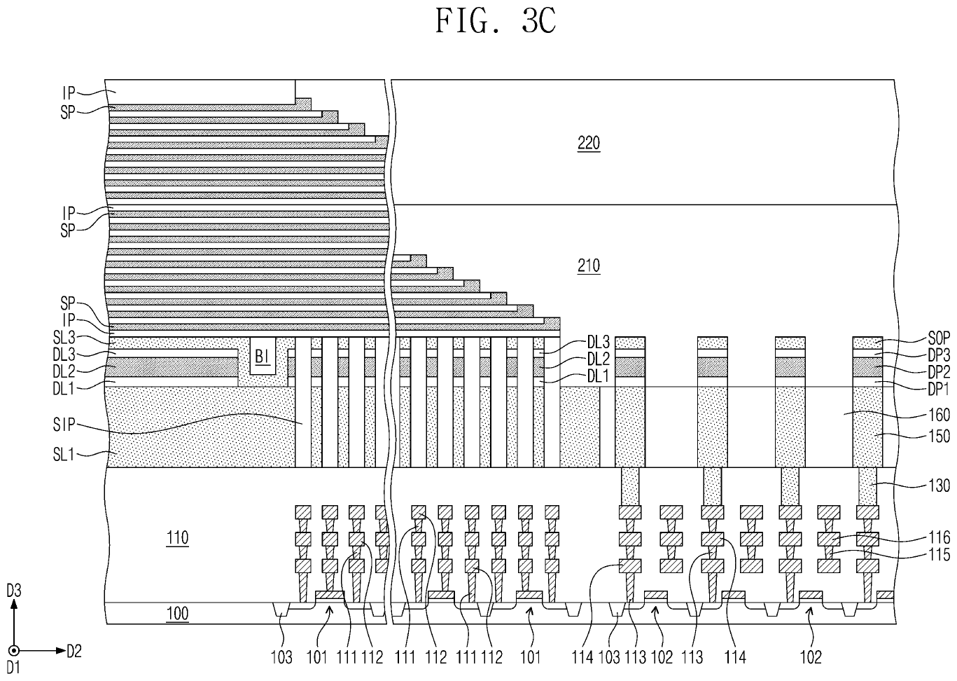

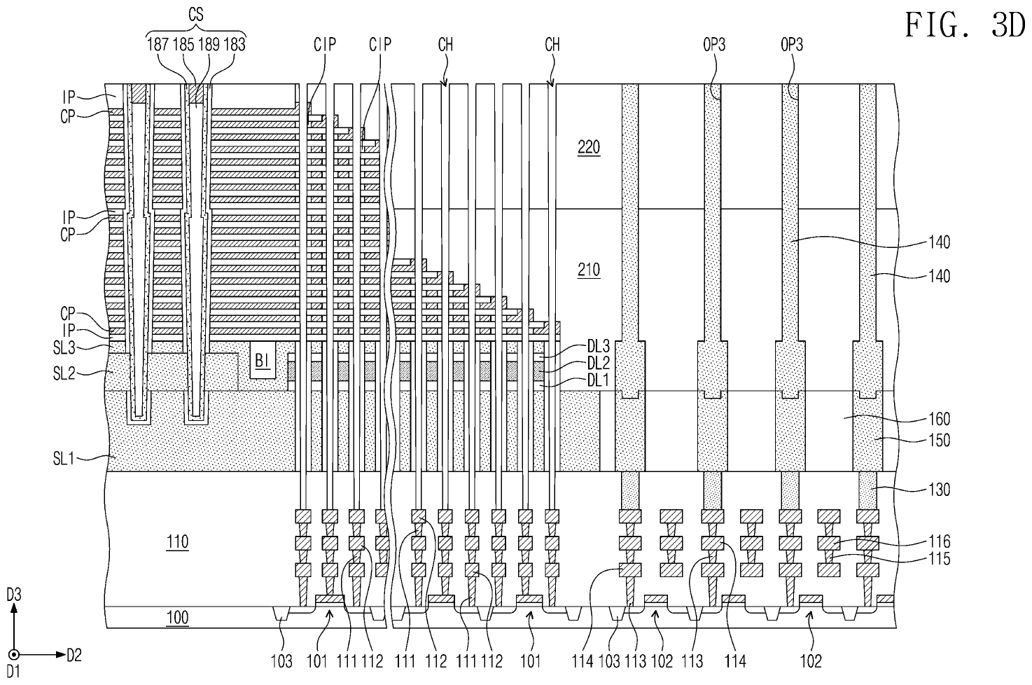

FIGS. 3A, 3B, 3C, and 3D are sectional views illustrating a method of fabricating a semiconductor device according to an embodiment of the present disclosure.

Referring to FIG. 3A, the first transistors 102, the second transistors 101, the device isolation layers 103, the first peripheral contacts 113, the second peripheral contacts 115, the third peripheral contacts 111, the first peripheral conductive lines 114, the second peripheral conductive lines 116, the third peripheral conductive lines 112, the connection vias 130, and the peripheral circuit insulating layer 110 may be formed on the substrate 100.

The formation of the connection via 130 may include forming a first opening OP1 in the peripheral circuit insulating layer 110 to expose the first peripheral conductive line 114 and forming the connection via 130 to fill the first opening OP1.

Referring to FIG. 3B, the first source layer SL1, the first capacitor electrodes 150, and the electrode insulating layer 160 may be formed on the peripheral circuit insulating layer 110. The formation of the first source layer SL1, the first capacitor electrodes 150, and the electrode insulating layer 160 may include forming a first preliminary source layer on the peripheral circuit insulating layer 110, forming second openings OP2 in the first preliminary source layer to divide the first preliminary source layer into the first source layer SL1 and the first capacitor electrodes 150, and forming the electrode insulating layer 160 to fill the second openings OP2.

Referring to FIG. 3C, the first dummy layers DL1, the second dummy layers DL2, the third dummy layers DL3, the third source layer SL3, first dummy patterns DP1, second dummy patterns DP2, third dummy patterns DP3, source patterns SOP, and the insulating gapfill layer BI may be formed.

The formation of the first dummy layers DL1, the second dummy layers DL2, the third dummy layers DL3, the third source layer SL3, the first dummy patterns DP1, the second dummy patterns DP2, the third dummy patterns DP3, the source patterns SOP, and the insulating gapfill layer BI may include forming a first preliminary dummy layer, forming a second preliminary dummy layer on the first preliminary dummy layer, forming a third preliminary dummy layer on the second preliminary dummy layer, forming a second preliminary source layer on the third preliminary dummy layer, forming the insulating gapfill layer BI on the second preliminary source layer, patterning the first preliminary dummy layer to form the first dummy layers DL1 and the first dummy patterns DP1, patterning the second preliminary dummy layer to form the second dummy layers DL2 and the second dummy patterns DP2, patterning the third preliminary dummy layer to form the third dummy layers DL3 and the third dummy patterns DP3, and patterning the second preliminary source layer to form the third source layer SL3 and the source patterns SOP. In an embodiment, the first to the third preliminary dummy layers and the second preliminary source layer may be patterned by a single process.

The first dummy pattern DP1 may be formed of or include the same insulating material as the first dummy layer DL1. As an example, the first dummy pattern DP1 may be formed of or include oxide. The second dummy pattern DP2 may be formed of or include the same insulating material as the second dummy layer DL2. As an example, the second dummy pattern DP2 may be formed of or include nitride. The third dummy pattern DP3 may be formed of or include the same insulating material as the third dummy layer DL3. As an example, the third dummy pattern DP3 may be formed of or include oxide. The source pattern SOP may be formed of or include the same conductive material as the third source layer SL3. As an example, the source pattern SOP may be formed of or include poly silicon.

The source insulating patterns SIP may be formed to extend through the third source layer SL3, the first to third dummy layers DL1, DL2, and DL3, and the first source layer SL1.

The insulating patterns IP and sacrificial patterns SP may be formed on the third source layer SL3 such that they are alternately stacked on top of one another. The sacrificial pattern SP may be formed of or include an insulating material. As an example, the sacrificial pattern SP may be formed of or include nitride. In an embodiment, the insulating patterns IP and the sacrificial patterns SP may be patterned to have a staircase structure.

The first staircase insulating layer 210 may be formed to cover the first to third dummy patterns DP1, DP2, and DP3 and the source pattern SOP. The second staircase insulating layer 220 may be formed on the first staircase insulating layer 210.

Referring to FIG. 3D, the memory channel structures CS may be formed to extend through the insulating pattern IP and the sacrificial pattern SP. A contact hole CH may be formed to extend through the insulating pattern IP, the sacrificial pattern SP, and the source insulating pattern SIP. The contact insulating patterns CIP may be formed to enclose the contact hole CH.

Then, the second capacitor electrodes 140 may be formed. The formation of the second capacitor electrode 140 may include forming a third opening OP3 to extend through the second staircase insulating layer 220 and the first staircase insulating layer 210 and expose the source pattern SOP and the first to third dummy patterns DP1, DP2, and DP3, removing the source pattern SOP and the first to third dummy patterns DP1, DP2, and DP3 to form empty regions, and forming the second capacitor electrode 140 to fill the empty regions and the third opening OP3. In an embodiment, the lowermost portion of the third opening OP3 may be placed in the first capacitor electrode 150. In this case, the first portion 143 (shown in FIG. 2H) of the second capacitor electrode 140 may be formed in the first capacitor electrode 150.

In an embodiment, the lowermost portion of the third opening OP3 may be at a level higher than the first capacitor electrode 150.

In an embodiment, a fourth opening (not shown) penetrating the insulating pattern IP and the sacrificial pattern SP may be formed during the formation of the third opening OP3. The sacrificial patterns SP may be replaced with the conductive patterns CP through the fourth opening. The first to third dummy layers DL1, DL2, and DL3, which are connected to the memory channel structure CS through the fourth opening, may be replaced with the second source layer SL2. The division structure DS may be formed in the fourth opening, as shown in FIG. 2C.

Referring to FIGS. 2A, 2B, and 2C, the connection contact CO may be formed to fill the contact hole CH. In an embodiment, the first cover insulating layer 230 and the second cover insulating layer 240 may be formed. Furthermore, the bit line contacts 251, the bit lines 252, the connection conductive lines 253, the electrode contacts 254, and the penetration vias 120 may be formed.

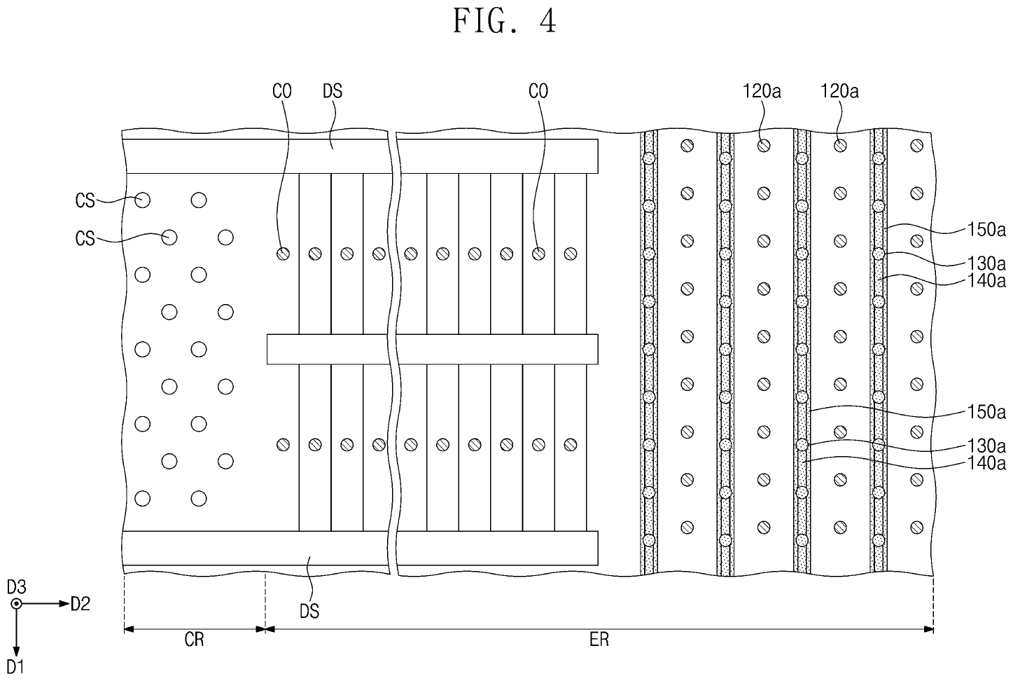

FIG. 4 is a plan view illustrating a semiconductor device according to an embodiment of the present disclosure.

Referring to FIG. 4, a semiconductor device may include a first capacitor electrode 150a and a second capacitor electrode 140a, which extend in the first direction D1. Connection vias 130a, which overlap with each first capacitor electrode 150a, may be arranged in the first direction D1 to form a connection via column. Penetration vias 120a, which are between two first capacitor electrodes 150a, may be arranged in the first direction D1 to form a penetration via column. The connection vias 130a of the connection via column and the penetration vias 120a of the penetration via column may be arranged to be offset from each other in the first direction D1. The connection via columns and the penetration via columns may be alternately arranged in the second direction D2.

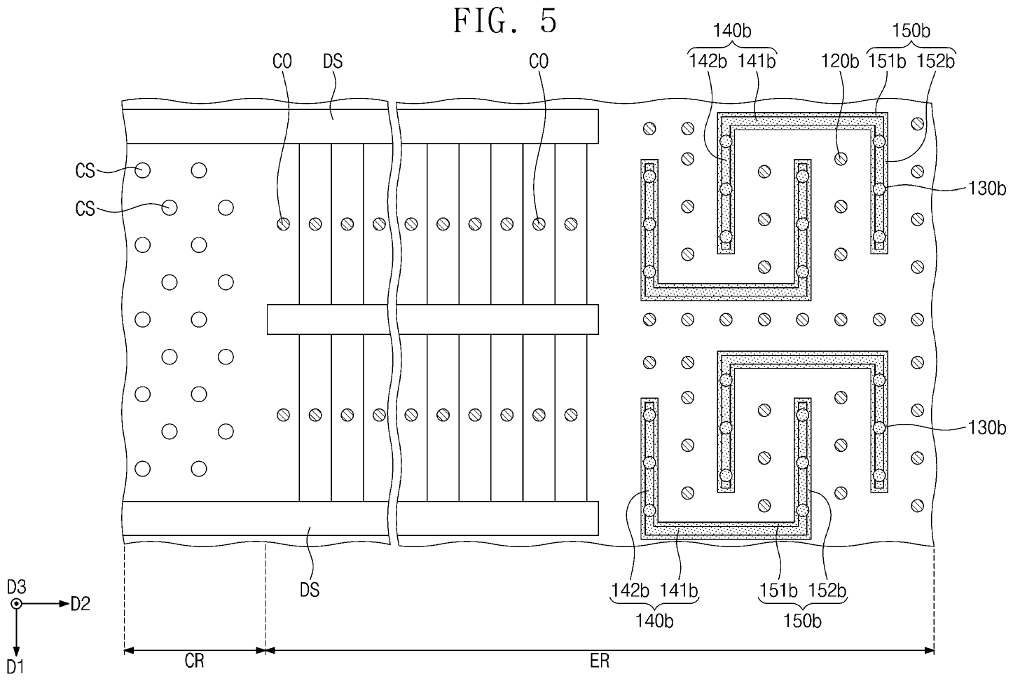

FIG. 5 is a plan view illustrating a semiconductor device according to an embodiment of the present disclosure.

Referring to FIG. 5, a first capacitor electrode 150b may include a first extended portion 151b, which extends in the second direction D2, and second extended portions 152b, which extend in the first direction D1. The second extended portions 152b of the first capacitor electrode 150b may be respectively connected to opposite end portions of the first extended portion 151b of the first capacitor electrode 150b.

A second capacitor electrode 140b may include a first extended portion 141b, which extends in the second direction D2, and second extended portions 142b, which extend in the first direction D1. The second extended portions 142b of the second capacitor electrode 140b may be respectively connected to opposite end portions of the first extended portion 141b of the second capacitor electrode 140b.

Connection vias 130b may overlap the second extended portions 152b and 142b of the first and second capacitor electrodes 150b and 140b in the third direction D3. Penetration vias 120b may be electrically isolated from the first and second capacitor electrodes 150b and 140b and the connection vias 130b.

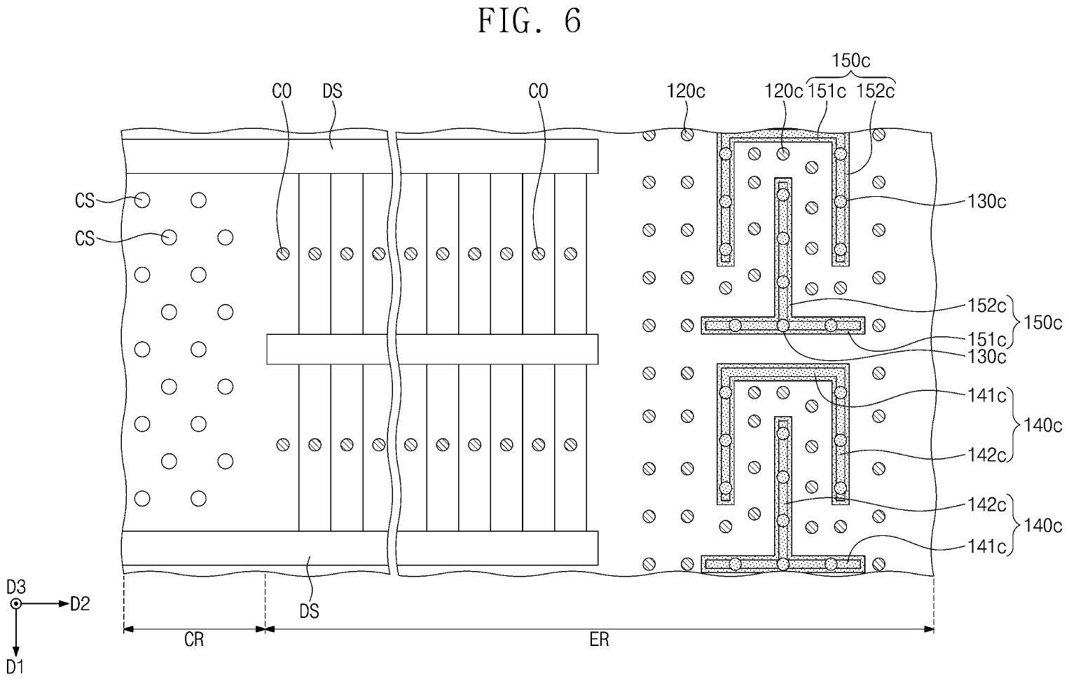

FIG. 6 is a plan view illustrating a semiconductor device according to an embodiment of the present disclosure.

Referring to FIG. 6, a first capacitor electrode 150c may include a first extended portion 151c, which extends in the second direction D2, and a second extended portion 152c, which extends in the first direction D1. At least one of the first capacitor electrodes 150c may include one first extended portion 151c and two second extended portions 152c. In an embodiment, at least one of the first capacitor electrodes 150c may include one first extended portion 151c and one second extended portion 152c.

A second capacitor electrode 140c may include a first extended portion 141c, which extends in the second direction D2, and a second extended portion 142c, which extends in the first direction D1. At least one of the second capacitor electrodes 140c may include one first extended portion 141c and two second extended portions 142c. In an embodiment, at least one of the second capacitor electrodes 140c may include one first extended portion 141c and one second extended portion 142c.

Connection vias 130c may overlap the first and second capacitor electrodes 150c and 140c in the third direction D3. Penetration vias 120c may be electrically isolated from the connection vias 130c and the first and second capacitor electrodes 150c and 140c.

In a semiconductor device according to an embodiment of the present disclosure and an electronic system including the same, a capacitor electrode structure including capacitor electrodes may be provided to have a relatively large size and, as such, a capacitor with a relatively large capacitance.

In a semiconductor device according to an embodiment of the present disclosure and an electronic system including the same, the capacitor electrode may include first and second extended portions preventing or suppressing a leaning issue of the capacitor electrode.

While example embodiments of the present disclosure have been particularly shown and described, it will be understood by one of ordinary skill in the art that variations in form and detail may be made therein without departing from the spirit and scope of the attached claims.

What is claimed is:

1. A semiconductor device, comprising:
a peripheral circuit structure;
a source structure on the peripheral circuit structure;
a first capacitor electrode on the peripheral circuit structure;
an electrode insulating layer that at least partially surrounds the first capacitor electrode;
a gate stack on the source structure;
a memory channel structure that extends through the gate stack;
a staircase insulating layer on the gate stack and the electrode insulating layer;
a second capacitor electrode on the first capacitor electrode and that extends through the staircase insulating layer; and
a penetration via that extends through the staircase insulating layer and the electrode insulating layer.

2. The semiconductor device of claim 1, wherein the first capacitor electrode at least partially surrounds the penetration via.

3. The semiconductor device of claim 1, wherein the second capacitor electrode at least partially surrounds the penetration via.

4. The semiconductor device of claim 1, wherein:
the source structure comprises a first source layer on the peripheral circuit structure and a second source layer on the first source layer,
the memory channel structure comprises a channel layer and a memory layer that at least partially surrounds the channel layer, and
the second source layer extends through the memory layer and contacts the channel layer.
the first capacitor electrode and the electrode insulating layer are at a same level as the first source layer.

5. The semiconductor device of claim 4, wherein:
a top surface of the first capacitor electrode, a top surface of the electrode insulating layer, and a top surface of the first source layer are coplanar with each other, and
a bottom surface of the first capacitor electrode, a bottom surface of the electrode insulating layer, and a bottom surface of the first source layer are coplanar with each other.

6. The semiconductor device of claim 1, wherein the second capacitor electrode comprises a first portion in the first capacitor electrode and a second portion on the first portion.

7. The semiconductor device of claim 6, wherein a width of the first portion of the second capacitor electrode is less than a width of the second portion of the second capacitor electrode.

8. The semiconductor device of claim 6, wherein the second capacitor electrode further comprises a third portion on the second portion of the second capacitor electrode, and
a width of the third portion of the second capacitor electrode is less than a width of the second portion of the second capacitor electrode.

9. The semiconductor device of claim 1, wherein the peripheral circuit structure comprises:
a transistor;
a first peripheral conductive line electrically connected to the transistor;
a connection via electrically connecting the first peripheral conductive line to the first capacitor electrode; and
a second peripheral conductive line electrically connected to the penetration via.

10. A semiconductor device, comprising:
a first source layer;
a second source layer on the first source layer;
a third source layer on the second source layer;
a first capacitor electrode at a same level as the first source layer;
an electrode insulating layer that at least partially surrounds the first capacitor electrode;
a second capacitor electrode on the first capacitor electrode;
a gate stack on the third source layer;
a memory channel structure that extends through the gate stack, the memory channel structure including a channel layer and a memory layer that at least partially surrounds the channel layer; and
a penetration via that extends through the electrode insulating layer,
wherein the second source layer extends through the memory layer and is connected to the channel layer.

11. The semiconductor device of claim 10, further comprising a peripheral circuit structure, wherein the peripheral circuit structure comprises:
a transistor;
a first peripheral conductive line electrically connected to the transistor;
a connection via electrically connecting the first peripheral conductive line to the first capacitor electrode; and
a second peripheral conductive line electrically connected to the penetration via.

12. The semiconductor device of claim 11, wherein the first peripheral conductive line and the second peripheral conductive line extend parallel to each other.

13. The semiconductor device of claim 11, wherein a bottom surface of the connection via is at a same level as a bottom surface of the penetration via.

14. The semiconductor device of claim 10, further comprising a division structure penetrating the gate stack,
wherein a top surface of the division structure is at a same level as a top surface of the second capacitor electrode.

15. The semiconductor device of claim 10, wherein the first capacitor electrode and the second capacitor electrode are electrically isolated from the penetration via.

16. The semiconductor device of claim 10, wherein:
the second capacitor electrode comprises a first extended portion that extends in a first direction, and
second extended portions that are respectively connected to opposite end portions of the first extended portion of the second capacitor electrode,
wherein the second extended portions of the second capacitor electrode extend in a second direction that intersects the first direction.

17. The semiconductor device of claim 10, wherein the electrode insulating layer comprises a first electrode insulating portion and a second electrode insulation portion, wherein the first capacitor electrode at least partially surrounds the first electrode insulation portion, and wherein the second electrode insulating portion at least partially surrounds the first capacitor electrode.

18. The semiconductor device of claim 10, wherein the gate stack comprises a staircase structure,
the semiconductor device further comprises a staircase insulating layer on the staircase structure, and
the staircase insulating layer comprises a first staircase insulating portion and a second staircase insulation portion, wherein the second capacitor electrode at least partially surrounds the first staircase insulating portion, and wherein the second staircase insulating portion at least partially surrounds the second capacitor electrode.

19. An electronic system, comprising:
a main substrate;
a semiconductor device on the main substrate; and
a controller on the main substrate and electrically connected to the semiconductor device,
wherein the semiconductor device comprises:
a peripheral circuit structure;
a source structure on the peripheral circuit structure;
a first capacitor electrode on the peripheral circuit structure;
an electrode insulating layer that at least partially surrounds the first capacitor electrode;
a gate stack on the source structure;
a memory channel structure that extends through the gate stack;
a staircase insulating layer on the gate stack and the electrode insulating layer;
a second capacitor electrode on the first capacitor electrode and that extends through the staircase insulating layer; and
a penetration via that extends through the staircase insulating layer and the electrode insulating layer,
wherein the peripheral circuit structure comprises:
a substrate;
a transistor on the substrate;
a peripheral circuit insulating layer on the transistor;
a first peripheral conductive line within the peripheral circuit insulating layer;
a second peripheral conductive line within the peripheral circuit insulating layer; and
a connection via within the peripheral circuit insulating layer,
wherein the transistor, the first peripheral conductive line, and the connection via are electrically connected to the first capacitor electrode, and
the second peripheral conductive line is electrically connected to the penetration via.

20. The electronic system of claim 19, wherein the memory channel structure comprises a channel layer and a memory layer that at least partially surrounds the channel layer, and
the source structure comprises:
a first source layer at a same level as the first capacitor electrode and the electrode insulating layer; and
a second source layer that extends through the memory layer and contacts the channel layer.
